(19) United States
(12) Patent Application Publication
(10) Pub. No.: US 2015/0259539 A1
(43) Pub. Date: Sep. 17, 2015

(54) SUPERHYDROPHOBIC AND LIPOPHOBIC SURFACES AND METHODS FOR THEIR MANUFACTURE

(71) Applicant: EMPIRE TECHNOLOGY DEVELOPMENT LLC, Wilmington, DE (US)

(72) Inventor: Kazufumi Ogawa, Awa-Shi (JP)

(21) Appl. No.: 14/435,205

(22) PCT Filed: Sep. 26, 2013
(86) PCT No.: PCT/US13/61948

§ 371 Date: Apr. 13, 2015

Related U.S. Application Data
(60) Provisional application No. 61/713,170, filed on Oct. 12, 2012.

(51) Int. Cl. C09D 1/00; C23C 14/06; B05D 5/08; C23C 16/06

(52) U.S. Cl. CPC C09D 1/00; C23C 16/06; C23C 14/06; B05D 5/083

(57) ABSTRACT

Optically transparent and translucent superhydrophobic and lipophobic surfaces are disclosed. The surfaces may be composed of a glass substrate on which multiple nano-particulates may be heat fused. The nano-particulates may be composed of metal oxides such as aluminum oxide or zinc oxide. Methods for fabricating such surfaces are also disclosed. In one method, a thin layer of a metal may be deposited on a substrate. The metal-covered substrate may be heated in an oxidizing atmosphere until the metal forms metal oxide nano particulates on the surface of the substrate. The heating process may also serve to fuse the nano-particulates onto the substrate.

### CROSS-REFERENCE TO RELATED APPLICATIONS

The present application claims the benefit of and priority to U.S. Provisional Application Ser. No. 61/713,170, entitled “Superhydrophobic And Lipophobic Surfaces And Methods For Their Manufacture,” which application was filed on Oct. 12, 2012. The aforementioned application is incorporated by reference herein in its entirety and for all purposes.

### BACKGROUND

Exterior window surfaces find many uses in both practical and aesthetic applications. Translucent windows may provide external lighting to interior spaces in a building while affording privacy to those inside. Clear windows are practical in automotive applications in which the driver must be able to see the road conditions while driving. Normal environmental conditions may, over time, coat the exterior window surfaces with dust, thereby decreasing visibility through the window as well as detracting from the aesthetics. Window cleaning may be a trivial chore for small, readily accessible windows, such as on a car. However, larger exterior windows, such as those that may be found on high-rise office buildings, may be less readily cleaned.

One method to reduce the effort of cleaning the exterior surfaces of such windows may be to produce a surface treatment of the window material that may resist adhering dust and promote self-cleaning during rain showers.

### SUMMARY

In an embodiment, a method for fabricating a superhydrophobic and lipophobic surface may include providing a transparent or translucent substrate having a surface, contacting at least a portion of the surface of the substrate with a film, thus forming a composite surface, heating at least a portion of the composite surface under a first condition so that at least a portion of the film may be converted to a number of aggregates in contact with the surface of the substrate, thus forming an aggregate surface, and heating the aggregate surface under a second condition so that at least a portion of the aggregates may be converted to a number of translucent projections from the surface of the substrate.

In another embodiment, a method for fabricating a superhydrophobic and lipophobic surface may include providing a transparent or translucent substrate having a surface, contacting at least a portion of the surface of the substrate with a film, thus forming a composite surface, and heating at least a portion of the composite surface under a condition so that at least a portion of the film is converted to a number of transparent projections from the surface of the substrate.

In yet another embodiment, a transparent or translucent superhydrophobic and lipophobic surface may include a transparent or translucent substrate composed of a first material and a number of transparent or translucent projections composed of a second material in which the projections may be heat fused onto a surface of the substrate.

### BRIEF DESCRIPTION OF THE DRAWINGS

FIGS. 1A-D illustrate an embodiment of a method for fabricating a superhydrophobic and lipophobic surface from a thick metal film-coated surface of a substrate in accordance with the present disclosure.

FIGS. 2A-C illustrate an embodiment of a method for fabricating a superhydrophobic and lipophobic surface from a thin metal film-coated surface of a substrate in accordance with the present disclosure.

### DETAILED DESCRIPTION

Human-manufactured surfaces, especially those exposed to outdoor environments, may become coated with dust and other fine particulates. In some instances, such dust merely detracts from the aesthetics of the surface. However, build-up of particulates may lead to surface wear. Additionally, if the surfaces are optical surfaces, such as windows, dust may reduce visibility and detract from the windows' main function. In some applications, windows (which may be transparent or translucent) may be sufficiently accessible that frequent cleaning may not pose a significant task. However, windows used in high-rise buildings and skyscrapers may be more difficult to access. In such instances, a window having a self-cleaning capability may reduce the need for difficult cleaning procedures. It may thus be appreciated that providing a method to treat an optical surface to give it self-cleaning properties may be beneficial with respect to cleaning and maintenance.

Naturally occurring structures having useful properties may serve as models for human-fabricated structures that may share the same properties. As one example, the surface structure of leaves of the lotus (for example, genus Nelumbo) may demonstrate a self-cleaning property. Lotus plants are aquatic, having broad leaves that float on top of the water's surface. The water habitat is often silty, and particulates can often fall on the leaf surface.

The upper surface of a lotus leaf may be composed of a large number of microscopic papillae covered with a waxy surface. The size of the papillae may not permit water droplets to wet the leaf surface since the contact angle between the water droplets and the leaf surface may be too great to break the surface tension of the droplets. Consequently, water droplets may not adhere to the surface. Additionally, water droplets on the leaf surface may be able to contact and hold dust particles associated on the surface and wash them off.

It is therefore desirable to develop a method for treating exterior window surfaces to induce micro-structures such as may be found on lotus leaves. Such a treatment, and the surfaces produced by the treatment, may result in a self-cleaning (rain induced) exterior window surface.

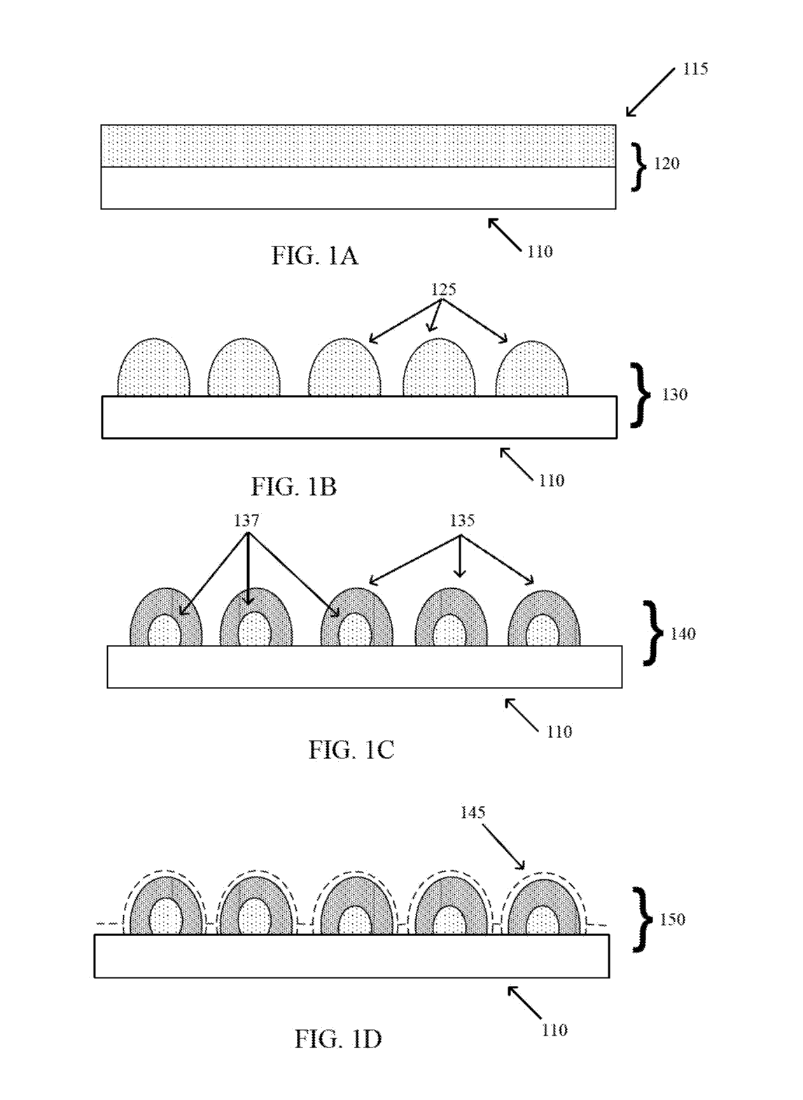

FIGS. 1A-D depict one embodiment of a method to impart such microstructures onto an optical surface. FIG. 1A depicts a transparent or translucent substrate 110 having a surface on which a film 115 may be deposited. The combination of the surface of the substrate 110 and film 115 together may be considered a composite surface 120. In some non-limiting embodiments, the substrate 110 may be composed of a glass, quartz, or sapphire, alone or in combination. In some non-limiting examples, the substrate 110 may be composed of a glass such as one or more of fused silica glass, soda lime glass, tempered glass, borosilicate glass, lead oxide glass, aluminosilicate glass, titansilicate glass, phosphate glass, and quartz.

In some embodiments, the film 115 may be a metal film composed of one or more of aluminum, zinc, and tin. The metal film 115 may be deposited on the surface of the substrate using any appropriate method including, but not limited to, chemical vapor deposition and physical vapor deposition. In one embodiment, the film 115 may have a thickness of about 50 nm to about 5000 nm. In one embodiment, the film 115 may have a thickness of about 200 nm to about 5000 nm. In one embodiment, the film 115 may have a thickness of about 20 nm to about 200 nm. Examples of film thickness may include, without limitation, about 50 nm, about 60 nm, about 80 nm, about 100 nm, about 200 nm, about 400 nm, about 600 nm, about 800 nm, about 1000 nm, about 1500 nm, about 2000 nm, about 2500 nm, about 3000 nm, about 4000 nm, about 5000 nm and ranges between any two of these values. In one non-limiting example, the metal film 115 may have a thickness of about 500 nm. In another non-limiting example, the metal film 115 may have a thickness of about 100 nm.

A composite surface 120 may be placed under conditions in which at least a portion of the film 115 may be converted to a number of film aggregates. FIG. 1B illustrates an example of such an effect. The conditions under which the composite 120 may be placed may include a first heating step. It may be appreciated that a composite surface 120 may be heated to a temperature sufficient to cause the metal film 115 to melt and form the metal aggregates 125 that may be associated with the surface of the substrate 110. It may be understood that such a heating step may rely on a temperature sufficient to melt the metal film 115 but not hot enough to soften or melt the substrate 110. The resulting material, including the surface of the substrate 110 and the aggregates 125, may be termed an aggregate surface 130. In one non-limiting embodiment, heating a composite surface 120 in which the metal film 115 is aluminum may include heating at least a portion of the composite surface to a temperature of about 380° C. to about 600° C. Examples of a heating temperature of the composite surface 120 having an aluminum film 115 may include, without limitation, a temperature of about 380° C., about 400° C., about 450° C., about 500° C., about 550° C., about 600° C., and ranges between any two of these values. Such temperatures may be useful for a substrate 110 made of glass and a film 115 made of aluminum. In one embodiment, the heating step of a composite surface 120 in which the metal film 115 is aluminum may be performed for about 15 minutes to about 60 minutes. Examples of a heating time for the composite surface 120 having an aluminum film 115 may include, without limitation, a time of about 15 minutes, about 20 minutes, about 25 minutes, about 30 minutes, about 40 minutes, about 50 minutes, about 60 minutes, and ranges between any two of these values. In one non-limiting example, the composite surface 120 having an aluminum film 115 may be heated for about 30 minutes.

In one embodiment, the conditions to which the composite surface 120 may be subjected may include being heated in a non-oxidizing atmosphere. In some non-limiting examples, the non-oxidizing atmosphere may include one or more of nitrogen, argon, helium, or any other atmosphere in which oxygen or oxygen-containing species are not present. It may be appreciated that water or water vapor may be included among oxygen-containing species, and thus the non-oxidizing atmosphere may include a dry gas. In another non-limiting example, the non-oxidizing atmosphere may include a vacuum having a pressure less than about 100 kPa (1 atmosphere).

The composite surface 120, after being treated in the manner disclosed above may thus form an aggregate surface 130. The aggregate surface 130 may be further treated by being subjected to a second set of conditions thereby forming a projection-containing surface 140 that may include a portion of the surface of the substrate 110 on which the projections 135 may be dispersed, as illustrated in FIG. 1C. The second set of conditions may include a second heating step under an oxidizing atmosphere. Non-limiting embodiments of an oxidizing atmosphere may include one or more of a gas, such as air, and a gas mixture comprising at least a portion of oxygen. In one non-limiting example, the aggregate surface may be heated at a temperature of about 300° C. to about a temperature at which the substrate may melt. In another non-limiting example, the second heating step may include heating an aggregate surface 130 derived from a composite surface 120 having an aluminum film 115 to a temperature of about 380° C. to about 660° C. Examples of a heating temperature of the aggregate surface 130 derived from a composite surface 120 having an aluminum film 115 may include, without limitation, a temperature of about 380° C., about 400° C., about 450° C., about 500° C., about 550° C., about 600° C., about 660° C., and ranges between any two of these values. In another non-limiting example, the second heating step may include heating an aggregate surface 130 derived from a composite surface 120 having a zinc film 115 to a temperature of about 270° C. to about 420° C. Additional examples of a heating temperature of an aggregate surface 130 derived from a composite surface 120 having a zinc film 115 may include, without limitation, a temperature of about 270° C., about 300° C., about 320° C., about 340° C., about 360° C., about 380° C., about 400° C., about 420° C., and ranges between any two of these values. In yet another non-limiting example, the second heating step may include heating an aggregate surface 130 derived from a composite surface 120 having a tin film 115 to a temperature of about 200° C. to about 230° C. Further examples of a heating temperature of the aggregate surface 130 derived from a composite surface 120 having a tin film 115 may include, without limitation, a temperature of about 200° C., about 205° C., about 210° C., about 215° C., about 220° C., about 225° C., about 230° C., and ranges between any two of these values.

In some embodiments, the second heating step may be performed for about 30 minutes to about 120 minutes. Examples of a heating time for the aggregate surface 130 may include, without limitation, a time of about 30 minutes, about 40 minutes, about 50 minutes, about 60 minutes, about 80 minutes, about 100 minutes, about 120 minutes, and ranges between any two of these values. In one non-limiting example, the second heating step of an aggregate surface 130 derived from a composite surface 120 having a film 115 of either zinc or tin may be performed for about 30 minutes.

It may be understood that the second set of treatment conditions may result in the metal aggregates 125 being oxidized to form the metal oxide projections 135. Thus, if the metal film 115 was initially aluminum, tin, or zinc, the projections 135 may be composed of the respective oxides, such as aluminum oxide, tin oxide, or zinc oxide. It may be appreciated that the projections 135 may be composed entirely of metal oxide. However, depending on the conditions of the second heating step—including temperature, time, pressure, and amount of oxygen available in the oxidizing atmosphere—the projections 135 may be composed of an exterior metal oxide layer and an interior core having some amount of unreacted metal 137. In addition to oxidizing the metal aggregates 125, the second heating step may also fuse the metal oxide projections 135 onto the surface of the substrate 110.

The dimensions of the projections 135 may depend on the initial metal film 115 thickness. In some non-limiting embodiments, the projections may have a height of about 20 nm to about 10000 nm, and a diameter of about 20 nm to about 10000 nm. In some non-limiting embodiments, the projections may have a height of about 200 nm to about 10000 nm, and a diameter of about 200 nm to about 10000 nm. In some non-limiting embodiments, the projections may have a height of about 20 nm to about 200 nm, and a diameter of about 20 nm to about 200 nm. Non-limiting examples of projection height may include about 20 nm, about 25 nm, about 30 nm, about 40 nm, about 50 nm, about 60 nm, about 70 nm, about 80 nm, about 90 nm, about 100 nm, about 200 nm, about 400 nm, about 600 nm, about 800 nm, about 1000 nm, about 2000 nm, about 4000 nm, about 5000 nm, about 7500 nm, about 10000 nm, and ranges between any two of these values. Non-limiting examples of projection diameter may include about 20 nm, about 25 nm, about 30 nm, about 40 nm, about 50 nm, about 60 nm, about 70 nm, about 80 nm, about 100 nm, about 200 nm, about 400 nm, about 600 nm, about 800 nm, about 1000 nm, about 2000 nm, about 4000 nm, about 5000 nm, about 7500 nm, about 10000 nm, and ranges between any two of these values.

It may be appreciated that a projection-containing surface 140 having projections 135 with dimensions less than a wavelength of visible light may be perceived as transparent, while a surface having projections with dimensions in the order of or greater than a wavelength of visible light may be perceived as translucent or dispersive. For example, a projection-containing surface 140, including projections 135 having a height of about 20 nm to about 100 nm, and a diameter of about 20 nm to about 100 nm may appear transparent to visible light (which may include radiation having a wavelength of about 350 nm to about 750 nm). As a non-limiting example, a projection-containing surface 140 having projections 135 with an average height of about 30 nm and an average diameter of about 80 nm may be perceived as transparent. In another non-limiting example, a surface 140 having projections 135 with an average height of about 100 nm and an average diameter of about 25 nm may also be perceived as transparent.

As disclosed above, the projections 135 may be dispersed on the surface of the substrate 110. The projections 135 may be dispersed uniformly on the surface of the substrate 110. In some non-limiting examples, the dispersion of projections 135 on the surface of the substrate 110 may be about 30% to about 70%. Non-limiting examples of projection 135 dispersion may include about 30%, about 40%, about 50%, about 60%, about 70%, and ranges between any two of these values.

While the projection-containing surface 140 may itself possess self-cleaning properties, the projection-containing surface may also be treated by adsorbing a monomolecular layer of a fluorocarbon material onto both the surface of the substrate 110 and the projections 135. Such a fluorocarbon treated surface 150 is illustrated in FIG. 1D which depicts the substrate 110 and the projections 135 coated with a monomolecular film of a fluorocarbon material 145. In a non-limiting example, the fluorocarbon coating may have a thickness of about 1 nm to about 2 nm. Examples of fluorocarbon materials may include, without limitation, one or more of a fluoroalkyl alkyl tri-chlorosilane having a formula of:

CF₃(CF₂)ₙ(CH₂)₂SiCl₃(n=3,5,7, or 9)

a fluoroalkyl alkyl tri-alkoxysilane having a formula of:

CF₃(CF₂)ₙ(CH₂)₂Si(OCH₃)₃(n=3,5,7, or 9)

a triclorosilyl-dimethylsiloxane having a formula of:

CH₃(Si(CH₃)₂O)ₘSiCl₃(m=1,2,3, or 4)

and/or a trialkoxy-dimethylsiloxane having a formula of:

CH₃(Si(CH₃)₂O)ₘSi(OCH₃)₃(m=1,2,3, or 4).

The resulting fluorocarbon-coated projection-containing surface 150 may exhibit significant water repellant properties due to the large contact angle that a water droplet may form with the surface. In one non-limiting example, the surface may form a contact angle greater than about 150 degrees (2.62 radians) with a surface of a water drop contacting with the surface. In another non-limiting example, a maximum water contact angle may be about 168 degrees (2.93 radians). Non-limiting examples of maximum water contact angles may include 150 degrees (2.62 radians), 151 degrees (2.64 radians), 152 degrees (2.65 radians), 153 degrees (2.67 radians), 154 degrees (2.69 radians), 158 degrees (2.75 radians), 160 degrees (2.79 radians), 162 degrees (2.83 radians), 164 degrees (2.86 radians), 166 degrees (2.90 radians), 168 degrees (2.93 radians), and ranges between any two of these values.

It is noted that the method disclosed above may find use for the preparation of projection-containing surfaces 140 or fluorocarbon-coated projection-containing surfaces 150 that may have been derived from the surface of the substrate 110 on which a thick film 115 has been applied. In this context, a thick film may be one having a thickness of about 500 nm to about 1000 nm. Under some conditions, the projection 135 height may reach of maximum of about twice the original thickness of the film 115. Thus, a surface of the substrate 110 coated with a layer of aluminum film 115 of about 750 nm may result in projections 135 having a maximum height of about 1500 nm. As disclosed above, projection-containing surface 140 or fluorocarbon-coated projection-containing surface 150 may be optically translucent if the projection height is about equal to or larger than at least one wavelength of visible light. Thus, a translucent surface having projections 135 about 1500 nm high may be prepared from a thick metal film 115 of about 750 nm.

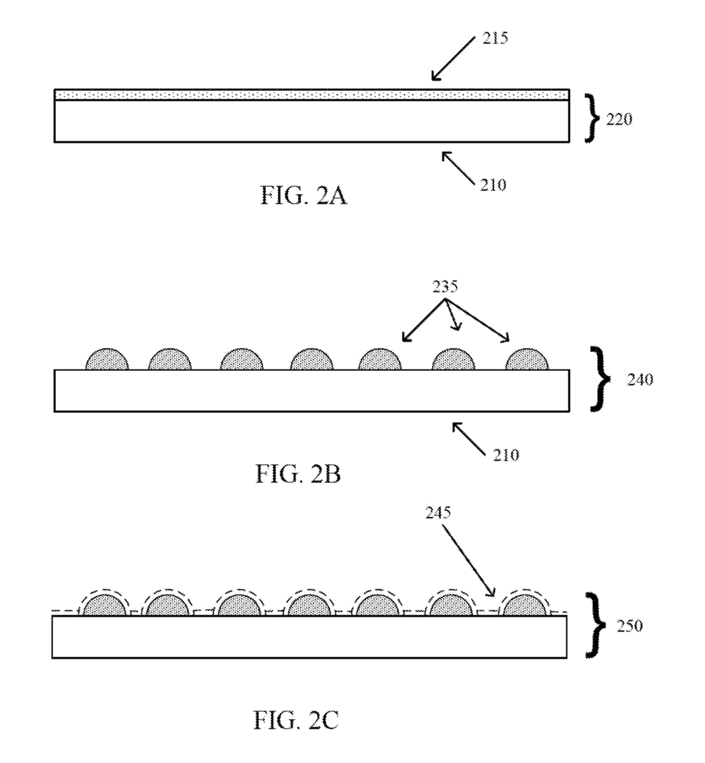

An optically transparent projection-containing surface may be prepared with projections having a maximum height less than a wavelength of visible light. If a lower boundary to visible light is taken as about 350 nm, then projections having a maximum height less than 350 nm may result in a projection-containing surface perceived as transparent. Thus, a film layer having a thickness less than half the wavelength of the lower boundary value for visible light (or less than about 175 nm) may be used to prepared a transparent projection-containing surface. FIGS. 2A-C illustrate an embodiment of a method to prepare such a transparent surface.

FIG. 2A depicts a composite surface 220 that may include a surface of the substrate 210 and a film 215 disposed on the surface of the substrate. In contrast to the film 115 thickness disclosed above with respect to FIG. 1A, film 215 may have a thickness of about 20 nm to about 200 nm. Non-limiting examples of a thin film thickness may include about 20 nm, about 30 nm, about 40 nm, about 50 nm, about 60 nm, about 70 nm, about 80 nm, about 90 nm, about 100 nm, about 120 nm, about 140 nm, about 160 nm, about 180 nm, about 200 nm, and ranges between any two of these values. In one non-limiting example, the metal film 215 may have a thickness of about 100 nm.

FIG. 2B illustrates the result of subjecting the composite surface 220 to a set of conditions. For a thin film 215, it may not be necessary to separate the aggregation step—heating under a non-oxidizing atmosphere—from the projection-forming step, which may include heating under an oxidizing atmosphere. In an embodiment involving thick films (FIGS. 1A-D), it may be necessary to heat the film to a liquefying temperature and allow the aggregates to form (FIG. 1B) before the aggregates may be oxidized (FIG. 1C). This may be due to the time needed to form the aggregates and amount of metal in them. In a thin-film embodiment illustrated in FIGS. 2A-C, the composite surface 220 may be heated to melting temperatures essentially the same as disclosed above with respect to the thick-film embodiment. Thus, the composite surface for a thin-film embodiment may be heated to a temperature greater than about the melting point of the film, and less than about the melting point of the substrate. In a non-limiting embodiment, the thin-film composite surface 220 having a film 215 of aluminum may be heated to a temperature of about 380° C. to about 600° C. In some non-limiting embodiments, the thin-film composite surface 220 having a film 215 of aluminum may be heated for about 15 minutes to about 60 minutes. In one non-limiting example, the composite surface may be heated for about 30 minutes.

It may be appreciated that the amount of material in the thin-film aggregates may be small, and, therefore, the time for aggregate formation may be short compared to the time for aggregate formation for film thicknesses and aggregate sizes disclosed in FIGS. 1A-D. As a result, the composite surface 220 may be heated directly in an oxidizing environment. Non-limiting examples of oxidizing environments may include environments containing air or a gas mixture including at least some portion of oxygen. The amount of time for this heating step may also be about the same as disclosed above with respect to the thick-film embodiment during the first heating step. The resulting projection-containing surface 240, as illustrated in FIG. 2B, may include metal oxide projections 235. In some embodiments, the projections developed from thin-film composite surfaces may have a height of about 20 nm to about 200 nm, and a diameter of about 20 nm to about 200 nm. Non-limiting examples of projection height may include about 20 nm, about 30 nm, about 40 nm, about 60 nm, about 70 nm, about 80 nm, about 90 nm, about 100 nm, about 120 nm, about 140 nm, about 160 nm, about 180 nm, about 200 nm, and ranges between any two of these values. Non-limiting examples of projection diameter may include about 20 nm, about 30 nm, about 40 nm, about 60 nm, about 70 nm, about 80 nm, about 90 nm, about 100 nm, about 120 nm, about 140 nm, about 160 nm, about 180 nm, about 200 nm, and ranges between any two of these values. As disclosed above with respect to equivalent projection-containing structure 140, the projections derived from the thin-film composite surfaces may be heat welded to the substrate as part of the projection-forming process.

In addition, as illustrated in FIG. 2C, the projection-containing surface 240 may be further coated with a monomolecular film 245 that may include a fluorocarbon material. The fluorocarbon material may be essentially the same as the material 145 disclosed above with respect to FIG. 1D.

### EXAMPLES

### Example 1

### A Method for Manufacturing a Thin-Film-Based Superhydrophobic Surface

A film of aluminum metal about 50 nm thick was deposited on a glass substrate. The film was heated at about 380° C. for about 30 minutes in an atmosphere containing oxygen. The resulting projections had a height of about 70 nm to about 80 nm high, and a substrate dispersal of about 40% to about 60%. The substrate with projections was coated with a fluorocarbon-based material having a thickness of about 1 nm to about 2 nm. The resulting surface was essentially transparent to visible light.

### Example 2

### A Method for Manufacturing a Thick-Film-Based Superhydrophobic Surface

A film of aluminum metal about 1000 nm thick was deposited on a glass substrate. The film was heated at about 600° C. for about 15 minutes in air. The resulting aggregates had a size of about 1000 nm.

### Example 3

### A Method for Manufacturing an Intermediate-Film-Based Superhydrophobic Surface

A film of aluminum metal about 100 nm thick may be deposited on a glass substrate. The film may then be heated at about 600° C. for about 60 minutes in air. The resulting aggregates may have a size of about 100 nm.

### Example 4

### Characteristics of a Superhydrophobic Surface

A superhydrophobic surface may include a glass substrate and a number of aluminum oxide projections effectively heat welded onto the surface of the glass. The projections may be essentially uniformly dispersed on the surface at about 40% to about 60%. The aggregates may have an average size of about 100 nm. Water droplets placed on the superhydrophobic surface may form a contact angle of about 153 degrees (2.67 radians).

### Example 5

### A Method for Forming an Optically Transparent Superhydrophobic Surface

A film of aluminum metal was deposited on a surface of a glass substrate. The film was about 60 nm thick. The film and the substrate were heated at about 400° C. for about 30 minutes in air, which resulted in the formation of a plurality of projections from the surface of the glass substrate. The projections that were formed had a height of about 70 nm. The glass substrate with the formed projections was coated with a monomolecular layer of fluoroalkyl alkyl tri-methoxysilane (CF₃(CF₂)₇(CH₂)₂Si(OCH₃)₃). The resulting treated substrate was analyzed with respect to its visible transmittance and surface water contact angle.

The visible transmittance of the treated substrate was measured by transmitting light of wavelength 540 nm from a surface of the treated substrate that had the projections and the fluorocarbon coating, to an opposite surface of the treated substrate. The visible transmittance of the treated substrate was measured to be about 94%, confirming that the treated substrate was essentially transparent to visible light.

Water droplets were placed at five different locations on the surface of the treated substrate that had the projections and the fluorocarbon coating. Table 1 shows the water contact angles measured at the five locations.

TABLE 1

| Location | 1 | 2 | 3 | 4 | 5 | Average |
|---|---|---|---|---|---|---|
| Contact Angle (°) | 150.8 | 152.5 | 152.0 | 150.3 | 152.3 | 151.6 |

The water contact angles at all five locations were found to be above 150°, and had an average water contact angle of about 151.6° (2.65 radians). These values demonstrated that the treated substrate has a superhydrophobic surface.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated in this disclosure, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used in this disclosure is for the purpose of describing particular embodiments only, and is not intended to be limiting.

With respect to the use of substantially any plural and/or singular terms in this disclosure, those having skill in the art can translate from the plural to the singular and/or from the singular to the plural as is appropriate to the context and/or application. The various singular/plural permutations may be expressly set forth in this disclosure for sake of clarity. It will be understood by those within the art that, in general, terms used in this disclosure, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed in this disclosure also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed in this disclosure can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described for purposes of illustration, and that various modifications may be made without departing from the scope and spirit of the present disclosure. Accordingly, the various embodiments disclosed are not intended to be limiting, with the true scope and spirit being indicated by the following claims.

1. A method for making a superhydrophobic and lipophobic surface, the method comprising:
providing a substrate with a surface, wherein the substrate is transparent or translucent;
contacting at least a portion of the surface of the substrate with a metal film, thereby forming a composite surface;
heating at least a portion of the composite surface under a first condition wherein at least a portion of the metal film is converted to a plurality of metal aggregates in contact with the surface of the surface, thereby forming an aggregate surface; and
heating the aggregate surface under a second condition, wherein at least a portion of the metal aggregates are converted to a plurality of projections from the surface of the substrate.

2. The method of claim 1, wherein contacting at least a portion of the surface of the substrate with a metal film comprises contacting at least a portion of the surface of the substrate with a film comprising one or more of the following metals: aluminum, zinc, and tin.

3. The method of claim 1, wherein contacting at least a portion of the surface of the substrate with a metal film comprises one or more of the following: depositing the metal film as a chemical vapor and depositing the metal film as a physical vapor.

4. The method of claim 1, wherein contacting at least a portion of the surface of the substrate with a metal film comprises contacting at least a portion of the surface of the substrate with a metal film having a thickness of about 200 nm to about 5000 nm.

5. (canceled)

6. The method of claim 1, wherein heating at least a portion of the composite surface under a first condition comprises heating at least a portion of the composite surface in a non-oxidizing atmosphere.

7. The method of claim 6, wherein heating at least a portion of the composite surface in a non-oxidizing atmosphere comprises heating at least a portion of the composite surface in one or more of: a nitrogen atmosphere, an argon atmosphere, and a helium atmosphere.

8. The method of claim 6, wherein heating at least a portion of the composite surface in a non-oxidizing atmosphere comprises heating at least a portion of the composite surface in a vacuum having a pressure less than about 100 kPa (1 atmosphere).

9. The method of claim 1, wherein heating at least a portion of the composite surface comprises heating at least a portion of the composite surface to a temperature greater than about a melting point of the metal film and less than about a melting point of the substrate.

10. (canceled)

11. The method of claim 1, wherein heating at least a portion of the composite surface comprises heating at least a portion of the composite surface for about 15 minutes to about 60 minutes.

12. (canceled)

13. The method of claim 1, wherein heating the aggregate surface under a second condition comprises heating the aggregate surface in an oxidizing atmosphere.

14. The method of claim 13, wherein heating the aggregate surface in an oxidizing atmosphere comprises heating the aggregate surface in one or more of: an air atmosphere and an atmosphere comprising a gas mixture comprising at least a portion of oxygen.

15. The method of claim 1, wherein heating at least a portion of the aggregate surface comprises heating at least a portion of the aggregate surface to a temperature of about 300° C. to about a melting point of the substrate.

16.-19. (canceled)

20. The method of claim 1, wherein heating at least a portion of the aggregate surface comprises heating at least a portion of the aggregate surface for about 30 minutes to about 120 minutes.

21. (canceled)

22. The method of claim 1, further comprising adsorbing a monomolecular layer of a fluorocarbon material onto the surface of the substrate and the plurality of projections.

23. (canceled)

24. A method for making a superhydrophobic and lipophobic surface, the method comprising:
providing a substrate with a surface, wherein the substrate is transparent or translucent;
contacting at least a portion of the surface of the substrate with a metal film, thereby forming a composite surface; and
heating at least a portion of the composite surface under a condition wherein at least a portion of the metal film is converted to a plurality of projections from the surface of the substrate.

25. The method of claim 24, wherein contacting at least a portion of the surface of the substrate with a metal film comprises contacting at least a portion of the surface of the substrate with a metal film having a thickness of about 20 nm to about 200 nm.

26. (canceled)

27. The method of claim 24, wherein heating at least a portion of the composite surface comprises heating at least a portion of the composite surface to a temperature greater than about a melting point of the metal film and less than about a melting point of the substrate.

28.-30. (canceled)

31. The method of claim 24, wherein heating at least a portion of the composite surface under a condition comprises heating at least a portion of the composite surface in an oxidizing atmosphere.

32. (canceled)

33. A transparent or translucent superhydrophobic and lipophobic surface comprising:
a substrate comprising a first material, wherein the substrate is transparent or translucent; and
a plurality of transparent or translucent projections comprising a second material,
wherein the plurality of projections are heat fused onto a surface of the substrate, and
wherein at least a portion of the plurality of projections comprise a metal core.

34. The surface of claim 33, wherein the first material is one or more of the following: a glass, quartz, and sapphire.

35. (canceled)

36. The surface of claim 33, wherein the second material is one or more of the following: aluminum oxide, zinc oxide, and tin oxide.

37. The surface of claim 33, wherein the plurality of projections have a height of about 20 nm to about 10,000 nm, and a diameter of about 20 nm to about 10,000 nm.

38.-40. (canceled)

41. The surface of claim 33, wherein the plurality of projections are dispersed uniformly on the surface of the substrate.

42. The surface of claim 33, wherein a dispersion of the plurality of projections on the surface is about 30% to about 70%.

43. The surface of claim 33, further comprising a fluorocarbon monolayer membrane chemically adsorbed on the surface of the substrate and the plurality of projections.

44.-45. (canceled)

46. The surface of claim 43, wherein the surface is configured to form a water contact angle of about 150 degrees to about 168 degrees with a surface of a water drop in contact with the surface.
